(19) United States
(12) Patent Application Publication
(10) Pub. No.: US 2025/0358950 A1
(43) Pub. Date: Nov. 20, 2025

(54) TWO-PIECE CENTER WALL FOR INFORMATION HANDLING SYSTEM CHASSIS CARRIER

(71) Applicant: Dell Products L.P., Round Rock, TX (US)

(72) Inventors: Megan Cherie WINGFIELD, Dalzell, SC (US); Daniel J. CAREY, Austin, TX (US)

(73) Assignee: Dell Products L.P., Round Rock, TX (US)

(21) Appl. No.: 18/665,137

(22) Filed: May 15, 2024

(51) Int. Cl. H05K 7/14

(52) U.S. Cl. CPC H05K 7/1489

(57) ABSTRACT

An information handling system may include one or more information handling resources and a carrier for housing the one or more information handling resources. The carrier may include a carrier cover and a carrier base mechanically coupled to the carrier cover. The carrier base may include a tray configured to mechanically couple to the one or more information handling resources and a wall. The wall may include a structural member mechanically coupled to the tray, the structural member comprising a continuous top surface having an uninterrupted geometry and a hem along the continuous top surface and an accessory member mechanically coupled to the structural member and extending above the continuous top surface.

### TECHNICAL FIELD

The present disclosure relates to modular information handling systems. More specifically, embodiments of the disclosure provide systems and methods for a two-piece center wall for an information handling system chassis carrier.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Oftentimes, information handling systems and other information handling resources (e.g., storage devices, input/output devices, and other peripheral devices) are each manufactured in a modular form factor and may be configured to be disposed in a chassis configured to receive such modular components. Such a chassis and its component modular information handling systems and information handling resources typically include various rails, carriers, and other mechanical components allowing for a person to add and remove the modular information handling systems and information handling resources from the chassis.

A carrier may generally include two major structural components, a base and a cover. The carrier may be supported by rails on either side of the chassis, and thus portions of the carrier base may sag or bow because the center of the carrier is often not supported by the rails. Such sagging and bowing may be problematic, as they may cause carriers to mechanically interfere with one other, component damage, or permanent deformation to a carrier.

### SUMMARY

In accordance with the teachings of the present disclosure, the disadvantages and problems associated with traditional approaches to forming a carrier for an information handling system chassis may be substantially reduced or eliminated.

In accordance with embodiments of the present disclosure, an information handling system may include one or more information handling resources and a carrier for housing the one or more information handling resources. The carrier may include a carrier cover and a carrier base mechanically coupled to the carrier cover. The carrier base may include a tray configured to mechanically couple to the one or more information handling resources and a wall. The wall may include a structural member mechanically coupled to the tray, the structural member comprising a continuous top surface having an uninterrupted geometry and a hem along the continuous top surface and an accessory member mechanically coupled to the structural member and extending above the continuous top surface.

In accordance with these and other embodiments of the present disclosure, a carrier for housing one or more information handling resources may include a carrier cover and a carrier base mechanically coupled to the carrier cover. The carrier base may include a tray configured to mechanically couple to the one or more information handling resources and a wall. The wall may include a structural member mechanically coupled to the tray, the structural member comprising a continuous top surface having an uninterrupted geometry and a hem along the continuous top surface and an accessory member mechanically coupled to the structural member and extending above the continuous top surface.

In accordance with these and other embodiments of the present disclosure, a wall for use in a carrier for an information handling system may include a structural member configured to mechanically couple to a tray of a carrier base of the carrier, the structural member comprising a continuous top surface having an uninterrupted geometry and a hem along the continuous top surface and an accessory member mechanically coupled to the structural member and extending above the continuous top surface.

In accordance with these and other embodiments of the present disclosure, a method for forming a wall for use in a carrier for an information handling system may include mechanically coupling a structural member to a tray of a carrier base of the carrier, the structural member comprising a continuous top surface having an uninterrupted geometry and a hem along the continuous top surface and mechanically coupling an accessory member to the structural member such that the accessory member extends above the continuous top surface.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a front perspective view of an example chassis for receiving modular information handling systems, in accordance with embodiments of the present disclosure;

FIG. 2 illustrates a top perspective view of an example carrier base, in accordance with embodiments of the present disclosure;

FIG. 3 illustrates a side perspective view of an example two-piece center wall for a carrier base, in accordance with embodiments of the present disclosure; and

FIG. 4 illustrates a side perspective view of an example single-piece center wall for a carrier base, in accordance with embodiments of the present disclosure.

### DETAILED DESCRIPTION

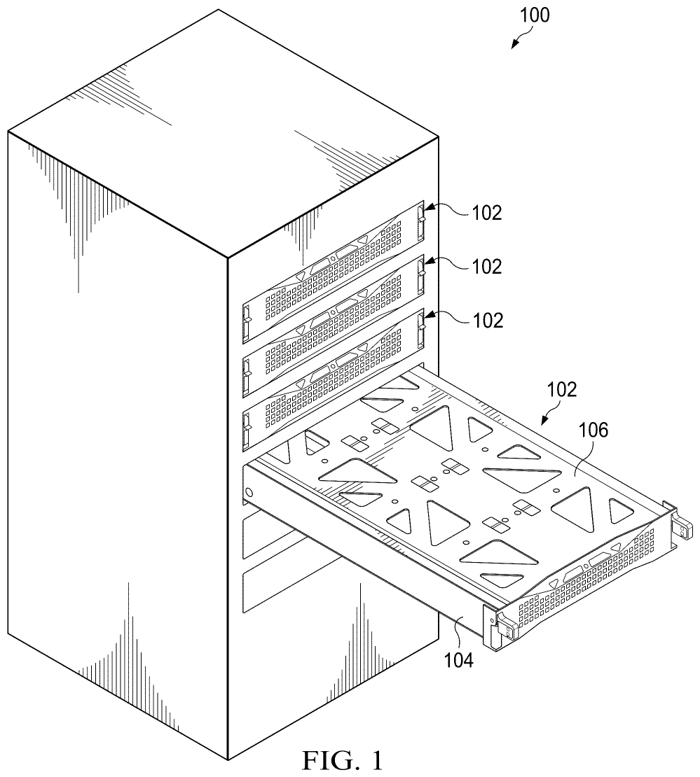

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

In this disclosure, the term “information handling resource” may broadly refer to any component system, device or apparatus of an information handling system, including without limitation processors, buses, memories, input-output devices and/or interfaces, storage resources, network interfaces, motherboards, electro-mechanical devices (e.g., fans), displays, and power supplies.

FIG. 1 illustrates a front perspective view of an example chassis 100 for receiving modular information handling resources 102, in accordance with embodiments of the present disclosure. Chassis 100 may be an enclosure that serves as a container for various information handling systems and information handling resources, and may be constructed from steel, aluminum, plastic, and/or any other suitable material. Although the term “chassis” is used, chassis 100 may also be referred to as a rack, case, cabinet, tower, box, enclosure, and/or housing. In certain embodiments, chassis 100 may be configured to hold and/or provide power to a plurality of information handling systems and/or information handling resources. As depicted in FIG. 1, chassis 100 may include one or more bays for receiving modular information handling systems 102.

An information handling system 102 may include a carrier (which may also be referred to as a sled), which may provide structural support for components of the information handling system 102. As shown in FIG. 1, a carrier may include a carrier base 104 and a carrier cover 106. Various electrical, electronic, and/or mechanical components may be placed within and mounted to carrier base 104, and carrier cover 106 may further be mechanically coupled to carrier base 104 to enclose such components within the carrier.

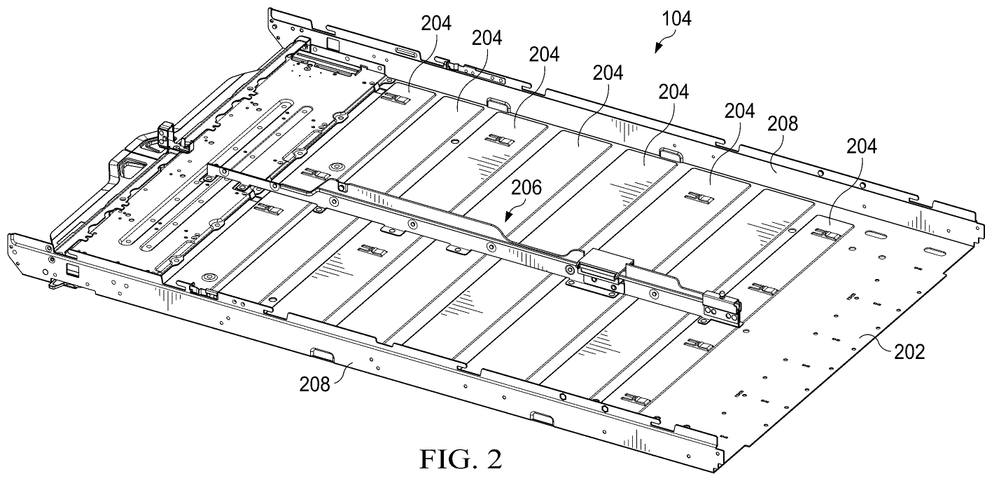

FIG. 2 illustrates a top perspective view of an example carrier base 104, in accordance with embodiments of the present disclosure. As shown in FIG. 2, carrier base 104 may include a tray 202 made of metal, plastic, and/or another suitable material which may have various features for mechanically mounting electrical, electronic, and/or mechanical components of an information handling system 102 to tray 202. Further as shown in FIG. 2, tray 202 may have one or more embosses 204 formed in the surface of tray 202 that may provide structural strength to tray 202. As also shown in FIG. 2, carrier base 104 may include a removable two-piece center wall 206 coupled to tray 202 along an approximate center line between side walls 208 of carrier base 104. Two-piece center wall 206 may also provide structural strength to tray 202 to minimize sagging and/or bowing of tray 202.

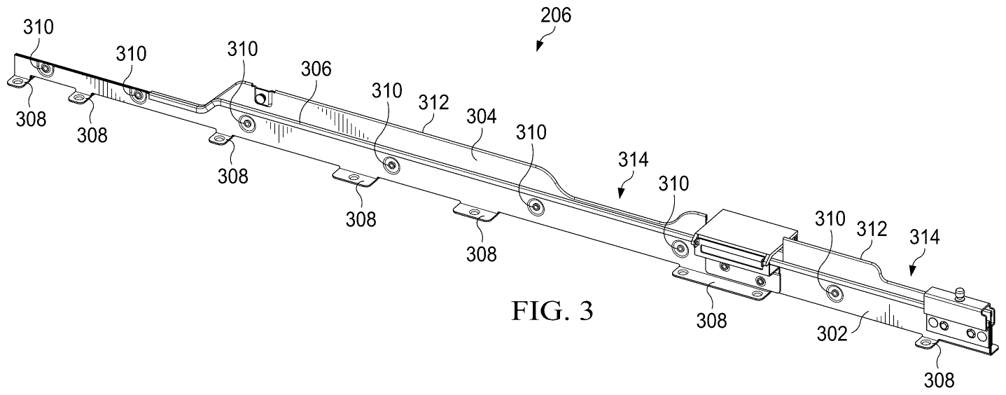

FIG. 3 illustrates a side perspective view of an example removable two-piece center wall 206 of carrier base 104, in accordance with embodiments of the present disclosure. As shown in FIG. 3, two-piece center wall 206 may comprise a structural member 302 and an accessory member 304 mechanically coupled to structural member 302.

As shown in FIG. 3, structural member 302 may comprise a continuous top surface 306 with a hem. Continuous top surface 306 may thus have an uninterrupted geometry which may provide the bulk of the stiffness, and thus the bulk of the structure, of two-piece center wall 206. As also shown in FIG. 3, structural member 302 may include tray mounting features 308 for mechanically coupling structural member 302 to tray 202. Further, structural member 302 may have accessory mounting features 310 for mechanically coupling accessory member 304 to structural member 302.

Accessory member 304 may be mechanically coupled to structural member 302 via coupling features (not shown) configured to mechanically interface with accessory mounting features 310. Accessory member 304 may be shaped and sized to accommodate the needs of information handling system 102. For example, in the embodiments represented by FIG. 3, accessory member 304 may include bulkheads 312 for engaging with and mechanically supporting carrier cover 106 and preventing air mixing between the two sides of information handling system 102. As another example, in the embodiments represented by FIG. 3, accessory member 304 may include cross-throughs 314 for allowing cables, hoses, and/or other components to pass from one side of information handling system 102 to the other. Because sufficient stiffness for carrier base 104 may be provided by structural member 302, accessory member 304 may be interrupted, perforated, bent, or otherwise shaped and/or sized as needed. Further, accessory member 304 may be removed from structural member 302 at will and replaced by a different form factor of accessory member 304 to accommodate the needs of information handling system 102.

To accommodate configurations with full-width components, two-piece center wall 206 may be removed and replaced with smaller brackets comprising bulkheads and supports, in which case stiffness for carrier base 104 may be provided by one or more tempans for a motherboard or other components.

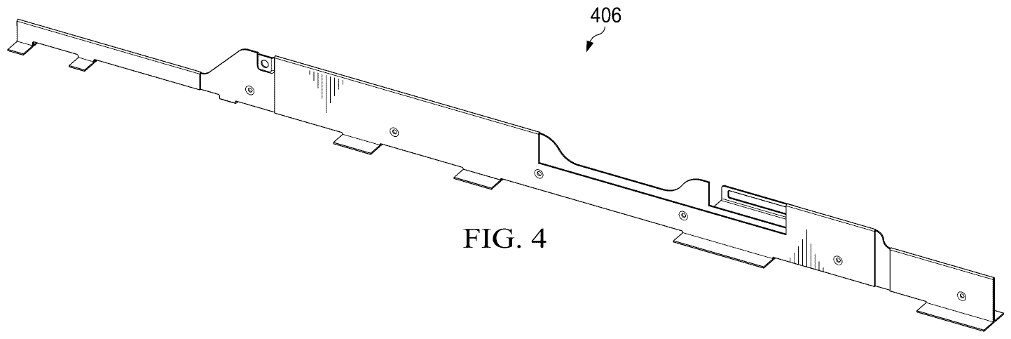

FIG. 4 illustrates a side perspective view of an example single-piece center wall 406 for a carrier base, which may be used in traditional approaches. Traditionally, center walls, such as single-piece center wall 406, are created out of a single piece of sheet metal bent over upon itself, with all necessary bulkheads, latches, and other features cut from or bent off from such single piece of sheet metal. Single-piece center wall 406 as shown in FIG. 4 matches the shape and functionality of two-piece center wall 206, and represents a structure that applicant created to simulate the structural effectiveness of two-piece center walls versus similarly-shaped and similarly-functional single-piece center walls. Applicant's simulations have shown that two-piece center walls (e.g., two-piece center wall 206) provide significantly greater stiffness over similarly sized and shaped single-piece center walls (e.g., single-piece center wall 406).

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system, comprising:
one or more information handling resources; and
a carrier for housing the one or more information handling resources, the carrier comprising:
a carrier cover; and
a carrier base mechanically coupled to the carrier cover and comprising:
a tray configured to mechanically couple to the one or more information handling resources; and
a wall comprising:
a structural member mechanically coupled to the tray, the structural member comprising a continuous top surface having an uninterrupted geometry and a hem along the continuous top surface; and
an accessory member mechanically coupled to the structural member and extending above the continuous top surface.

2. The information handling system of claim 1, wherein the accessory member includes:
one or more bulkheads for engaging with and mechanically supporting the carrier cover; and
one or more cross-throughs for allowing cables, hoses, and/or other components to pass from one side of the wall to the other.

3. A carrier for housing one or more information handling resources, the carrier comprising:
a carrier cover; and
a carrier base mechanically coupled to the carrier cover and comprising:
a tray configured to mechanically couple to the one or more information handling resources; and
a wall comprising:
a structural member mechanically coupled to the tray, the structural member comprising a continuous top surface having an uninterrupted geometry and a hem along the continuous top surface; and
an accessory member mechanically coupled to the structural member and extending above the continuous top surface.

4. The carrier of claim 3, wherein the accessory member includes:
one or more bulkheads for engaging with and mechanically supporting the carrier cover; and
one or more cross-throughs for allowing cables, hoses, and/or other components to pass from one side of the wall to the other.

5. A wall for use in a carrier for an information handling system comprising:
a structural member configured to mechanically couple to a tray of a carrier base of the carrier, the structural member comprising a continuous top surface having an uninterrupted geometry and a hem along the continuous top surface; and
an accessory member mechanically coupled to the structural member and extending above the continuous top surface.

6. The wall of claim 5, wherein the accessory member includes:
one or more bulkheads for engaging with and mechanically supporting a carrier cover or the carrier; and
one or more cross-throughs for allowing cables, hoses, and/or other components to pass from one side of the wall to the other.

7. A method for forming a wall for use in a carrier for an information handling system comprising:
mechanically coupling a structural member to a tray of a carrier base of the carrier, the structural member comprising a continuous top surface having an uninterrupted geometry and a hem along the continuous top surface; and
mechanically coupling an accessory member to the structural member such that the accessory member extends above the continuous top surface.

8. The method of claim 7, wherein the accessory member includes:
one or more bulkheads for engaging with and mechanically supporting a carrier cover or the carrier; and
one or more cross-throughs for allowing cables, hoses, and/or other components to pass from one side of the wall to the other.
